(19) United States
(12) Patent Application Publication
(10) Pub. No.: US 2002/0084456 A1
(43) Pub. Date: Jul. 4, 2002

(54) Multilayered wiring board and production method thereof

(75) Inventors: Osamu Sugihara, Kofu-shi (JP); Tsutomu Asakawa, Yamanashi-ken (JP)

Correspondence Address: COOK, ALEX, McFARRON, MANZO,, CUMMINGS & MEHLER, LTD., Suite 2850, 200 West Adams Street, Chicago, IL, 60606, US

(73) Assignee: Hoya Corporation

(21) Appl. No.: 09/948,964

(22) Filed: Sep. 7, 2001

(30) Foreign Application Priority Data
Sep. 11, 2000 (JP) 2000-275317
Aug. 10, 2001 (JP) 2001-244673

(51) Int. Cl. H01L 21/66; G01R 31/26; H01L 23/58; H01L 29/40

(52) U.S. Cl. 257/48; 438/14; 438/15; 438/18; 257/758; 438/622

(57) ABSTRACT

There are provided a multilayered wiring board for a wafer batch contact board and production method thereof which can form condensers at low costs without changing the volume of the board (area and height, particularly height). The multilayered wiring board is a multilayered wiring board which constitutes a portion of a wafer batch contact board or the like used for testing a plurality of semiconductor devices formed on a wafer simultaneously and which has the structure that wiring patterns laminated via an insulating layer are connected (or conducted) to each other via a contact hole formed in the insulating layer, wherein condensers 11 are formed between the wiring patterns in the multilayered wiring layer integrally.

This application claims the Paris convention priority of Japanese patent applications 2000-275317 filed on Sep. 11, 2000 and 2001-244673 filed on Aug. 10, 2001, the entire disclosure of which is incorporated herein by reference.

### BACKGROUND OF THE INVENTION

(i) Field of the Invention

The present invention relates to a multilayered wiring board which constitutes a portion of a contact jig used for testing (or inspecting) a semiconductor device and to the production method of the board.

(ii) Description of the Related Art

An inspection of a plurality of semiconductor devices (semiconductor chips) formed on a wafer is broadly divided into production inspection (electric characteristic test) by a probe card and a burn-in test which is a reliability test to be conducted after the production inspection.

The burn-in test is one of screening tests to be conducted for removing semiconductor devices which have inherent defects or devices which would have failures ascribable to time and stress due to variations in the production. While the inspection by the probe card is an electric characteristic test of a produced device, the burn-in test can be said to be a heat acceleration test.

To conduct the burn-in test, a conventional system (one chip burn-in system) in which a wafer is cut into chips by dicing and packaged after the electric characteristic test is conducted on each chip by the probe card and the burn-in test is conducted on each of the chips lacks practicability from the viewpoint of costs. Under the circumstances, the development and commercialization of a wafer batch contact board (burn-in board) for conducting the burn-in test on all semiconductor devices formed on a wafer at a time is under way (Japanese Patent Application Laid-Open No. 231019/1995). A wafer batch burn-in system using the wafer batch contact board is highly practicable from the viewpoint of costs. Further, it is also an important technology which helps achieve the latest streams of technology such as shipments of bare chips and mounting of bare chips.

The details of the burn-in test will be described step by step hereinafter.

Static burn-in is a burn-in test in which a rated power supply voltage or a voltage higher than the rated power supply voltage is applied at high temperatures to pass an electric current through a device so as to exert temperature and voltage stresses on the device. This is also called “high-temperature bias test”.

Dynamic burn-in is a burn-in test which is conducted while a signal close to that used in actual operation is impressed to the input circuit of a device by applying a rated power supply voltage or a voltage higher than the rated power supply voltage at high temperatures.

Monitored burn-in is a dynamic burn-in test which also has the function of monitoring the characteristics of the output circuit.

Test burn-in is a burn-in test which can evaluate a device to be tested.

The properties required for the wafer batch contact board are different from those required for a conventional probe card in that the wafer batch contact board is used for inspecting ail semiconductors on a wafer simultaneously and that the wafer batch contact board is used in a heat test, and the level of the required properties is high. When the wafer batch contact board goes into actual use, not only the aforementioned burn-in test (including the case where an electric characteristic test is conducted) but also a part of the production inspection (electric characteristic test) which has heretofore been conducted by the probe card can be conducted by the wafer batch contact board.

A specific example of the wafer batch contact board is shown in FIG. 6.

As shown in FIG. 6, the wafer batch contact board has the structure that a contact component 30 is fixed on a multilayered wiring board 10 for a wafer batch contact board (to be referred to as “multilayered wiring board 10” hereinafter) via an anisotropic conductive rubber sheet 20.

The contact component 30 serves as a contact component which makes direct contact with devices to be inspected. As for the contact component 30, bumps 33 are formed on one surface of a membrane 32 made of a insulating film, and pads 34 are formed on the other surface thereof. The membrane 32 spans between rings 31 having a low thermal expansion coefficient so as to avoid the displacement of the membrane 32 due to thermal expansion. The bumps 33 correspond to the electrodes formed on the periphery or center line of each semiconductor device (chip) on a wafer 40 (about 600 to 1,000 pins per chip, electrodes exist on the wafer for the number of these pins multiplied by the number of chips) and are formed at the corresponding positions for the number of the electrodes.

A multilayered wiring board 10 has wiring and pad electrodes for sending a predetermined burn-in signal or the like to each of the bumps 33 isolated on the membrane 32 via the pad 34 formed on an insulating board. The multilayered wiring board 10 has a multilayered wiring structure because its wiring is complicated. Further, the multilayered wiring board 10 uses an insulating board having a low thermal expansion coefficient in order to avoid connection failure casued by its displacement relative to the pads 34 on the membrane 32 due to thermal expansion.

An anisotropic conductive rubber sheet 20 is a sheet contact component comprising an elastic body (anisotropic conductive rubber made of a silicon resin and having metal particles embedded at the points corresponding to the above pads and the above pad electrodes) having conductivity only in the direction perpendicular to the main surface and electrically connects the pad electrodes (not shown) on the multilayered wiring board 10 to the pads 34 on the membrane 32. The anisotropic conductive rubber sheet 20 makes contact with the pads 34 on the membrane 32 by means of the anisotropic conductive rubber projections (not shown) formed on the surface of the sheet, whereby the elasticity and flexibility of the rubber and the flexibility of the membrane 32 synergistically absorb the unevenness of the surface of the semiconductor wafer 40 and variations in the heights of the bumps 33, so that the electrodes on the semiconductor wafer are connected to the bumps 33 on the membrane 32 securely.

Each semiconductor device (chip) has electrodes (pad electrodes) one of which (power supply electrode) is used as a power supply terminal of an integrated circuit, another of which (ground electrode) is used as a ground terminal of the integrated circuit and the others of which (signal electrodes) are used as signal input/output terminals (signal terminals) of the integrated circuit. The bumps 33 on the wafer batch contact board are formed and connected to the electrodes on the semiconductor chip in a one-to-one relationship. Further, in the multilayered wiring in the wafer batch contact board, a power supply line, a ground line and a signal input/output line (signal line) are shared for the purpose of decreasing the number of lines.

When a multi-burn-in test in which a burn-in test is conducted on a plurality of chips formed on a wafer simultaneously or a wafer batch burn-in test in which a burn-in test is conducted on all the chips formed on a wafer simultaneously is conducted, a power supply voltage and a signal must be applied to the electrodes on each semiconductor chip on the wafer simultaneously to activate a plurality or all of the semiconductor chips.

Under the circumstances, a contactor (contact jig) which is capable of bringing probe electrodes into contact with a plurality of pad electrodes on the wafer simultaneously has been proposed. According to this technique, a plurality of bumps are formed on the contactor, and these bumps are used as contact electrodes.

A conventional contactor for a wafer batch burn-in apparatus must have high flatness (about ±50 μm) in order to cause the bumps formed on the contactor to contact the electrodes on a wafer at a time securely.

Meanwhile, in the case of a burn-in test using a wafer batch burn-in appratus, a plurality of semiconductor chips must be activated simultaneously. In this case, to activate the plurality of semiconductor chips simultaneously, a large amount of electric current must be momentarily supplied to the wafer at the beginning of the activation of the chips. When such a large amount of electric current is supplied to the wafer, there occur such problems that a power supply voltage drops significantly due to the wiring resistance of the contactor and that voltages to be supplied to adjacent semiconductor chips drop in turn.

To solve such problems, there are proposed such techniques that condensers are attached to the wiring layer of the contactor and that condensers are provided on the back of a wiring board supporting the wiring layer by making holes in the wiring board.

However, in the case of the method in which condensers are attached to the wiring layer, since the condensers are bulky, the above-described flatness of the contactor cannot be maintained, thereby making secure batch contact of the bumps and the electrodes on the wafer difficult.

Meanwhile, in the case of the method in which condensers are formed on the back of the wiring board, a step requiring a high degree of processing accuracy such as a step of forming the holes in the wiring board is additionally provided, so that there exist such problems as low yields and a significant increase in costs.

In addition, particularly in the case of a multilayered wiring board for a wafer batch contact board, it has been found that ideally, a condenser must be formed for each chip or at least for a couple of chips. However, when condensers are formed on a multilayered wiring board for inspecting a wafer having several hundreds to 1,000 chips or more formed thereon by the above methods, there occur such problems that enormous time and efforts are required and that costs become large.

The above problems also exist in the case of a multilayered wiring board which constitutes a portion of a contact jig used for testing semiconductor devices, for example, a multilayered wiring board which constitutes a portion of a contact jig used for inspecting a plurality of semiconductor devices simultaneously.

The present invention has been invented under the above circumstances. An object of the present invention is to provide a multilayered wiring board in which condensers are formed on the wiring board at low costs with the flatness of the wiring board maintained and production method thereof.

Particularly, it is an object of the present invention to provide a multilayered wiring board or a multilayered wiring board for a wafer batch contact board and production methods thereof which can attain an ideal structure in which a condenser is formed for each chip or a structure in which a condenser is formed at least for a couple of chips at low costs and can therefore remove errors caused by the noises produced in switching each chip completely or alleviate the influence of the noises so that the characteristics of the board can be fully exploited.

### SUMMARY OF THE INVENTION

To achieve the above objects, the present invention has the following constitutions.

(Constitution 1) A multilayered wiring board which constitutes a portion of a contact jig used for testing semiconductor devices and which has the structure that wiring patterns laminated via an insulating layer are connected (or conducted) to each other via a contact hole formed in the insulating layer, wherein condensers having a capacity of 50 pF to 50 μF are formed between the wiring patterns or between lines in the same layer.

(Constitution 2) The board of constitution 1, wherein the contact jig is used for inspecting a plurality of semiconductor chips simultaneously, and each of the condensers is provided for one semiconductor chip or for a plurality of semiconductor chips.

(Constitution 3) The board of constitution 1, wherein the contact jig is a wafer batch contact board used for testing a plurality of semiconductor chips formed on a wafer at a time, and each of the condensers is provided for one semiconductor chip or for a plurality of semiconductor chips on the wafer.

(Constitution 4) The board of any of constitutions 1 to 3, wherein the conductive film constituting the condenser is formed in the step in which the wiring pattern is formed.

(Constitution 5) The board of any of constitutions 1 to 4, wherein the condenser is formed between at least one of power supply lines and a GND line.

(Constitution 6) The board of any of constitutions 1 to 5, which comprises a power supply common line provided in the multilayered wiring layer for the purpose of electrically connecting the power supply electrodes of the same type in a plurality of semiconductor chips to each other,

a GND common line provided in the multilayered wiring layer for the purpose of electrically connecting the GND electrodes in the plurality of semiconductor chips to each other,

power supply branch lines which branch from the power supply common line and connect the corresponding power supply electrode to the power supply common line, GND branch lines which branch from the GND common line and connect the corresponding GND electrode to the GND common line, and

a condenser provided between the power supply common line and the GND common line.

(Constitution 7) The board of constitution 6, wherein the condenser is formed between a power supply branch line and a ground branch line in the multilayered wiring board which correspond to the power supply electrode and the GND electrode in each of the semiconductor chips, respectively.

(Constitution 8) The board of any of constitutions 1 to 7, wherein the dielectric material constituting the condenser is a material containing titanium oxide.

(Constitution 9) The board of any of constitutions 1 to 8, wherein the dielectric layer constituting the condenser has a thickness of 500 angstrom to 20 μm.

(Constitution 10) A method for producing a multilayered wiring board which constitutes a portion of a contact jig used for testing semiconductor devices and has the structure that wiring patterns laminated via an insulating layer are connected (or conducted) to each other via a contact hole formed in the insulating layer, the method including the step of forming a condenser by forming a dielectric layer on a portion of the area where the upper wiring pattern and the lower wiring pattern overlap each other three-dimensionally or the step of forming a condenser by forming a dielectric layer between lines in the same layer on a portion of the area where the lines are close to each other.

(Constitution 11) The method of constitution 10, wherein the conductive film constituting the condenser is formed in the step of forming the wiring patterns.

(Constitution 12) The method of constitution 11, which further comprises the steps of:

forming a first wiring pattern having a dielectric layer formed on the surface,

forming an insulating layer on the dielectric layer formed on the first wiring pattern,

forming a contact hole for connecting wiring patterns laminated with the insulating layer therebetween to each other in the insulating layer and forming an opening for forming a condenser in the insulating layer, forming a protective layer in the opening to protect it, removing the dielectric layer exposed in the contact hole, and then removing the protective layer, and

forming a second wiring pattern on the insulating layer, connecting (or conducting) the first wiring pattern and the second wiring pattern to each other via the contact hole and forming a condenser in the opening.

(Constitution 13) The method of constitution 11, which further comprises the steps of:

forming a first wiring pattern,

forming an insulating layer on the first wiring pattern,

forming a contact hole for connecting wiring patterns laminated with the insulating layer therebetween to each other in the insulating layer and forming an opening for forming a condenser in the insulating layer, forming a protective layer at least in the contact hole to protect it, forming a dielectric layer in the opening formed in the insulating layer, and then removing the protective layer, and

forming a second wiring pattern on the insulating layer, connecting (or conducting) the first wiring pattern and the second wiring pattern to each other via the contact hole and forming a condenser in the opening.

(Constitution 14) A contact jig comprising the multilayered wiring board of constitutions 1 to 9 and a contact component which makes direct contact with devices to be inspected.

(Constitution 15) The contact jig of constitution 14, which is a wafer batch contact board.

(Constitution 16) A method for inspecting a plurality of semiconductor chips (devices) simultaneously by using the contact jig of constitution 14.

(Constitution 17) A method for inspecting a plurality of semiconductor devices formed on a semiconductor wafer by subjecting all the semiconductor devices to a burn-in test simultaneously using the wafer batch contact board of constitution 15.

(Constitution 18) A multilayered wiring board having the structure that wiring patterns laminated via an insulating layer are connected (or conducted) to each other via a contact hole formed in the insulating layer, wherein condensers are formed between the wiring patterns or between lines in the same layer in the multilayered wiring layer.

According to the present invention, by forming interlayer condensers between the upper wiring pattern and the lower wiring pattern or forming in-plane condensers between lines in the same layer in a multilayered wiring board constituting a portion of a contact jig (contactor) used for testing semiconductor devices, the condensers can be formed at low costs without changing the volume (area and height, particularly height and flatness) of the board.

Particularly, when a plurality of semiconductor chips are inspected simultaneously, an ideal structure in which a condenser is formed for each chip or a structure in which a condenser is formed at least for a couple of chips can be attained at low costs, and errors caused by the noises produced in switching each chip can therefore be removed completely or the influence of the noises can be alleviated, so that the characteristics of the board can be fully exploited.

### BREIF DESCRIPTION OF THE DRAWINGS

FIG. 1 is a cross-sectional diagram showing the substantial part of the multilayered wiring board for a wafer batch contact board according to one example of the present invention for illustrating its production process.

FIG. 2 is a cross-sectional diagram showing the substantial part of the multilayered wiring board for a wafer batch contact board according to one example of the present invention for illustrating its production process.

FIG. 3 is a schematic diagram showing the positions at which condensers are formed in the multilayered wiring board for a wafer batch contact board.

FIG. 4 is a schematic diagram showing the positions at which condensers are formed in the multilayered wiring board for a wafer batch contact board.

FIG. 5 is a cross-sectional diagram showing the substantial part of the multilayered wiring board for a wafer batch contact board according to another example of the present invention for illustrating its production process.

FIG. 6 is a schematic diagram showing the wafer batch contact board.

Reference numeral 1 denotes a glass board; 2 a Cu film; 3 a TiO₂ film; 4 a Cr/Cu/TiO₂ multilayered wiring layer; 4a a first wiring pattern; 5 and 5′ insulating layers; 6 and 6′ contact holes; 7 and 7′ openings for forming condensers; 8 a protective resist pattern; 9 a Cr/Cu multilayered wiring layer; 9a a second wiring pattern; 10 a multilayered wiring board; 11 a condenser; 12 a multilayered wiring layer; 13 a protective insulating film; 14 a contact portion (opening); 15 a portion for forming a condenser; 16 a resist layer; 17 a TiO₂ film (ferroelectric film); 18 a third conductive layer; 18a a third wiring pattern; 19 a condenser counter electrode; 20 an anisotropic conductive rubber sheet; 30 a contact component; 31 a ring; 32 a membrane; 33 a bump; and 34 a pad.

### DETAILED DESCRIPTION OF THE PREFERRED EMBODIMENT

A description will be given to the embodiments of the present invention hereinafter.

The multilayered wiring board for a contact jig of the present invention has the structure that condensers are formed between the upper wiring pattern and the lower wiring pattern or between lines in the same layer in the multilayered wiring layer (including the uppermost wiring layer).

The contact jig of the present invention includes a probe card for testing one or more semiconductor chips and a wafer batch contact board for testing a plurality or all of semiconductor chips on a wafer.

Although the positions of the condensers are not particularly limited, they may be formed, for example, (1) between at least one of power supply lines (including a power supply line having its area enlarged as large as possible) and a GND line (including a GND line having its area enlarged as large as possible), (2) between a power supply common line and a GND common line, or (3) between a power supply branch line and a ground branch line. An embodiment in which the condensers are formed at a plurality of these positions (1) to (3) may also be included. These condensers may be formed on each line. These condensers are bypass condensers between a power supply and a ground.

Further, interlayer condensers may be formed between any wiring patterns one of which is above the other in the multilayered wiring layer (including the uppermost wiring layer). This also applies to the constitutions 12 and 13.

It is preferable that condensers between power supplies and a ground have different capacities. This is because it is preferable to adjust the capacities of the condensers according to the frequency components of expected noises.

A condenser capacity C is calculated from the following expression.

C=εᵣ×S/d (εᵣ: relative dielectric constant, S: area of condenser electrode (three-dimensionally overlapped area between laminated wiring patterns), d: film thickness of dielectric layer)

When a condenser is formed for each chip or for a couple of chips, since the area in which the condenser can be formed is limited, the area of the condenser electrode is preferably as small as possible. Specifically, although depending on the sizes of devices (chips) to be inspected and the specifications of measurement accuracy, the area of the condenser electrode is preferably not larger than 1 cm², more preferably not larger than 5 mm².

When a condenser is formed between a power supply common line and a GND common line or between at least one of power supply lines and a GND line, the above limitation associated with the area is alleviated.

When the area of the condenser electrode is determined by the above expression, since the condenser capacity is inversely proportional to the thickness of a dielectric film and proportional to the relative dielectric constant of the dielectric film, the thickness of the dielectric film must be made as thin as possible and the relative dielectric constant of the dielectric film must be made as big as possible in order to increase the condenser capacity. However, the thickness of the dielectric film must be such that the dielectric film would not have dielectric breakdown, and a material that can be molded and processed easily must be selected as the material of the dielectric.

The capacity of a condenser in the multilayered wiring board for a wafer batch contact board must be changed to a proper capacity (capacity suitable for a wafer batch burn-in test) as appropriate according to the electric current value of the corresponding device. When the capacity of the condenser is too small, the device cannot secure an electric current (supplied from the condenser) needed for the operation of the device, so that the chip on the wafer may not operate. On the other hand, when the capacity of the condenser is too large, it takes too much time to charge the condenser, whereby the timing at which an electrical current is discharged from the condenser is delayed, so that the device does not operate.

When a condenser is formed for each chip or for a couple of chips, the capacity of the condenser is preferably 50 pF to 50 μF. This is because when the capacity of the condenser is smaller than 50 pF, a drop in power supply voltage due to wiring resistance cannot be inhibited and the effect of reducing noises cannot be obtained satisfactorily. On the other hand, when the capacity of the condenser is larger than 50 μF, inductance becomes further excessively large disadvantageously. The capacity of the condenser is preferably 50 pF to 0.1 μF, more preferably 50 pF to 1 nF, much more preferably 300 to 800 pF.

The location at which the condenser is formed is not particularly limited. However, the condenser is more preferably formed as close to a chip with a large electric current as possible.

The thickness of a dielectric layer constituting the condenser is preferably 100 angstrom to 20 μm, more preferably 500 angstrom to 20 μm, much more preferably 5,000 angstrom to 5 μm, the most preferably 1 to 5 μm. This is because when the thickness of the dielectric layer is too small, the dielectric layer lacks strength and may therefore have dielectric breakdown, while when the thickness of the dielectric layer is too large, the etchability of the dielectric layer is impaired, whereby precise patterning may not be conducted easily.

Although a method for forming the condenser is not particularly limited, a conductive film constituting the condenser is preferably formed in the step of forming a wiring pattern by patterning a wiring layer. Thus, when the condenser is formed not in the step of attaching the condenser to the wiring layer but in the step of forming the wiring pattern, a condenser with a small footprint can be formed by a simple process. Further, unlike the case where the condenser is attached to the wiring layer, costs for purchasing and mounting the condenser are not needed, and the condenser can be formed at low costs.

The conducive films (conductive films formed above and under the dielectric layer) constituting the condenser may be portions of the wiring patterns or be formed without using the portions of the wiring patterns. However, it is preferable to use the portions of the wiring patterns (or to use the same materials as the wiring patterns) since the step of forming the condenser can be simplified.

When the step of forming an insulating layer on a wiring pattern having a dielectric layer formed thereon and removing the dielectric layer exposed in a contact hole formed in the insulating layer is carried out in the formation of the condenser, it is desirable to select a dielectric material and an etching method which make it possible to etch a dielectric with a minimum influence to other materials constituting the board.

When a dielectric material layer is formed in the opening for forming the condenser, processability such as etching is not significant.

An example of the dielectric material and the processing method will be described hereinafter.

When barium titanate (such as Ba₂TiO₄ or Ba₂TiO₃; dielectric constant: 2,900 to 5,000), strontium titanate (such as Sr₂TiO₄ or Sr₂TiO₃) or Rochelle salt (KnaC₄H₄O₆: dielectric constant: 4,000) is used as the dielectric material, sputtering, vacuum evaporation, a method of sintering a coated sol-gel solution or lift-off method may be used as a method (film-forming method) for forming the dielectric material layer. The etching method (processing method) may be a wet etching method using an HF-based etching solution. When these dielectric materials are used, a condenser of the order of picofarad to microfarad can be formed. Since these dielectric materials may not be easily removed by etching, they are suitable for the case where the dielectric material layer is formed by using a method of forming the dielectric material layer in the opening for forming the condenser. Further, a titanate-based dielectric material layer can be subjected to patterning by the lift-off method.

When titanium oxide (such as TiO₂; dielectric constant: 85) is used as the dielectric material layer, a method (film-forming method) for forming the dielectric material layer may be, for example, a method in which TiO₂ is formed directly by sputtering, CVD or a method of sintering a coated sol-gel solution or a method in which a Ti film is formed by sputtering or CVD and then subjected to thermal oxidation or anodic oxidation to form TiO₂. The etching method (processing method) may be, for example, a dry etching method using a fluorine-containing gas (such as CF₄/O₂ mixed gas) or a wet etching method using a fluoride-containing etching solution (such as a mixed solution of hydrofluoric acid and nitric acid) or a chlorine-containing etching solution. When TiO₂ is used as the dielectric material, a condenser of the order of picofarad to nanofarad can be formed. Since TiO₂ is excellent in etchability and removability by etching, it is suitable for the case where the dielectric material layer is formed by using the etching method.

When CuO (dielectric constant: 12) is used as the dielectric material, a method (film-forming method) for forming the dielectric material layer may be, for example, a method in which the surface of a wiring layer made of Cu which is a main wiring material is subjected to thermal oxidation. The etching method (processing method) may be, for example, a wet-etching method using an etching solution such as a ferric chloride (FeCl₃) aqueous solution. Although the capacity of a condenser is an order of picofarad to nanofarad when Cuo is used as the dielectric material, the condenser can be formed easily since the surface of the wiring layer is used.

When NiO is used as the dielectric material, a method (film-forming method) for forming the dielectric material layer may be, for example, a method in which the surface of a Ni wiring layer formed on Cu which is a main wiring material is subjected to thermal oxidation or anodic oxidation. The etching method (processing method) may be, for example, a wet-etching method using a chlorine-containing etching solution. Although the capacity of a condenser is an order of picofarad to nanofarad when NiO is used as the dielectric material, the condenser can be formed easily since the surface of the wiring layer is used.

When a polyimide (dielectric constant: 3.2) is used as the dielectric material, a method (film-forming method) for forming the dielectric material layer may be, for example, spin coating. The processing method may be, for example, a method of exposing and developing a photosensitive polyimide. When the polyimide is used as the dielectric material, this method is the simplest method from the viewpoint of the steps constituting the method since the polyimide as the material of the insulating layer can be used. However, the method also has the problem that the capacity of the condenser is smaller than the above dielectric material.

The thickness of the polyimide dielectric material layer can be adjusted to a desired thickness by, for example, a method of controlling the exposure and development of the photosensitive polyimide to attain the desired thickness, a method of dry-etching the polyimide to attain the desired thickness or a method of coating a polyimide in the opening for forming the condenser to a desired thickness.

Further, as the dielectric material, compounds such as BaSnO₃, Ba₁₋ₓSrₓTiO₃, BaTaO₆, BaTiO₃, Baₓ(Sr, Pb)₁₋ₓTi_{y}(Sn, Zr)_{1-y}O₃, BaZrO₃, Bi₂Sn₂O₇, Bi₂Sr₃O₉, Bi₄Ti₃O₁₂, Bi₁₂TiO₂O, BiTaO₄, Bi₂Ti₄O₁₁, Bi₃TiTaO₉, Bi₃TiNbO₉, Bi₂RuO_{7.3}, CaBi₂Nb₂O₉, CaBi₂Ta₂O₉, CaBi₄Ti₄O₁₆, CaTiO₃, LiNbO₃, MgTiO₃, PbBi₂Nb₂O₉, PbBi₂Ta₂O₉, Pb₂Bi₄Ti₁₅O₁₈, PbLaₓTi_{y}O_{σ}, PLZT (generic name for oxides of Pb, La, Zr and Ti), PbTiO₃, PZT (generic name for oxides of Pb, Zr and Ti) , PZT+PbO, SrBiO₄, Sr₂Bi₂O₅, SrBi₂Nb₂O₉, Sr₂Bi₄Ti₆O₁₈, SrNb₂O₆, Sr₂Nb₂O₇, SrTa₂O₆, Sr₂Ta₂O₇, SrTiO₂ and (Zr, Sn)TiO₄ can be used. Further, in some cases, organic ferroelectric materials such as PET (polyethylene terephthalate), PP (polypropylene) and PS (polystyrene) may also be used.

A condenser using a solid dielectric has a smaller size, a larger capacitance and better heat resistance than a condenser having air or the like sandwiched between conductive plates. Therefore, it is preferable to use the solid dielectric. The dielectric materials can be used solely or in admixture of two or more, and known additives and addition agents can also be added to the solid dielectric. Further, as the solid dielectric material, titanium oxide, barium titanate, strontium titanate or the like are preferable, and they may be used solely or in admixture of two or more. Illustrative examples of the additives to be added to these dielectric materials include BaSnO₃, BaZrO₃, MgTiO₃ and CaTiO₃. By adding these additives, the relative dielectric constant and temperature characteristics of the dielectric materials can be controlled.

Further, illustrative examples of the method for forming the dielectric material layer include vacuum dry film-forming methods such as sputtering, vapor deposition and CVD, a sol-gel method or a wet method such as spin coating of a solvent.

In the multilayered wiring board of the present invention, the material of the insulating layer is preferably a resin material. Illustrative examples of the resin material include an acrylic resin, an epoxy resin and a polyimide. of these, a polyimide having a low thermal expansion coefficient and excellent heat resistance and chemical resistance is particularly preferable.

The insulating layer can be formed on a glass board or on a wiring layer by, for example, spin coating, roller coating, curtain coating, spray coating, printing or the like.

As for the wiring layer, for example, a thin conductive film is formed on the board or on the insulating layer by a thin-film-forming method such as sputtering, EB vapor deposition, electrolytic plating, electroless plating or lift-off and subjected to photolithography (application of resist, exposure, development, etching and the like) to obtain wiring having a desired pattern.

The wiring materials and layer structure of the wiring layer are not particularly limited. For example, the wiring layer may have a Cr/Cu/Ni multilayered structure, a Cu/Ni/Au multilayered structure or a Cr/Cu/Ni/Au multilayered structure, with Cr being a main wiring material and closest to the board.

In the wiring layer, Cr and Ni can prevent the oxidation of Cu which is liable to be oxidized (corrosion resistance is improved particularly by Ni), and Cr and Ni exhibit good adhesion to Cu as well as to their adjacent layers other than Cu (for example, an Au layer in the case of Ni, and the glass board and the insulating layer in the case of Cr), so that the adhesion between the layers can be improved.

As a substitute for Cu which is the main wiring material, Al, Mo and the like can be used. The film thickness of Cu which is the main wiring material is preferably 0.5 to 50 μm, more preferably 0.5 to 15 μm, much more preferably 1.0 to 7.0 μm, the most preferably 2.5 to 6 μm.

As a substitute for Cr which is a substrate film, metals such as W, Ti, Al, Mo, Ta, Cr and Si and alloys thereof can be used.

As a substitute for Ni, a high-melting-point metal or the like having high adhesion can be used from the viewpoint of its relationship with the materials constituting the layers above and below Ni.

As a substitute for Au, Au, Ag, Pt, Ir, Os, Pd, Rh, Ru and the like can be used.

In the case of the multilayered wiring board, although gold or the like is coated on the wiring surface of the uppermost layer (outermost surface) for the purposes of preventing the oxidation of the wiring surface, protecting the wiring surface and decreasing a contact resistance, gold or the like does not need to be coated on the surfaces of the underlying layers (internal layers) underneath the uppermost layer. However, in consideration of the contact resistance, coating the internal wiring layers with gold does not cause any problems except for an increase in costs.

Gold can be post-coated on the wiring surface. Alternatively, a wiring pattern may be formed by preparing a multilayered wiring layer having gold or the like coated on the whole outermost surface in advance and wet etching this multilayered wiring layer in turn.

A description will be given to Examples hereinafter.

### Example 1

### Preparation of Multilayered Wiring Board

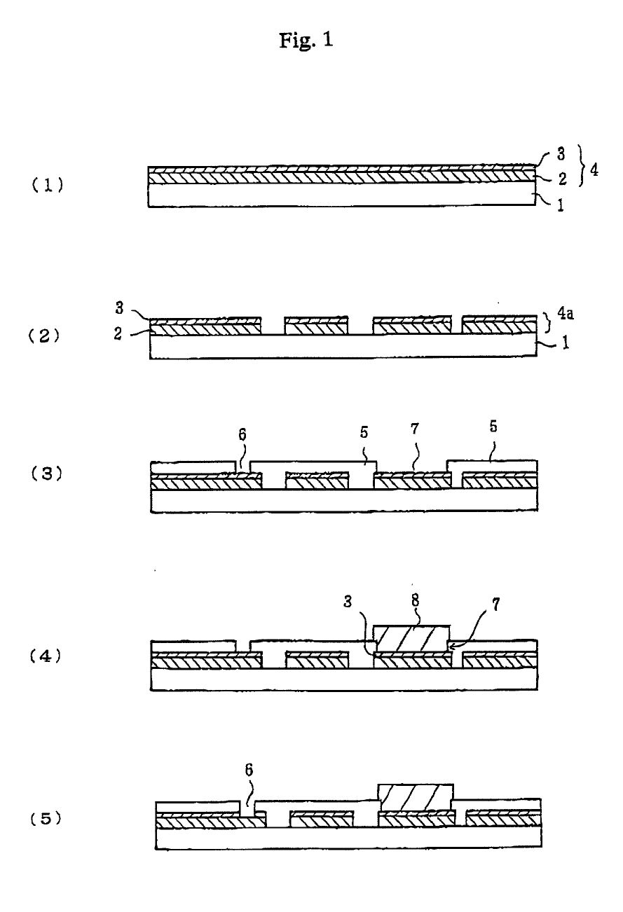

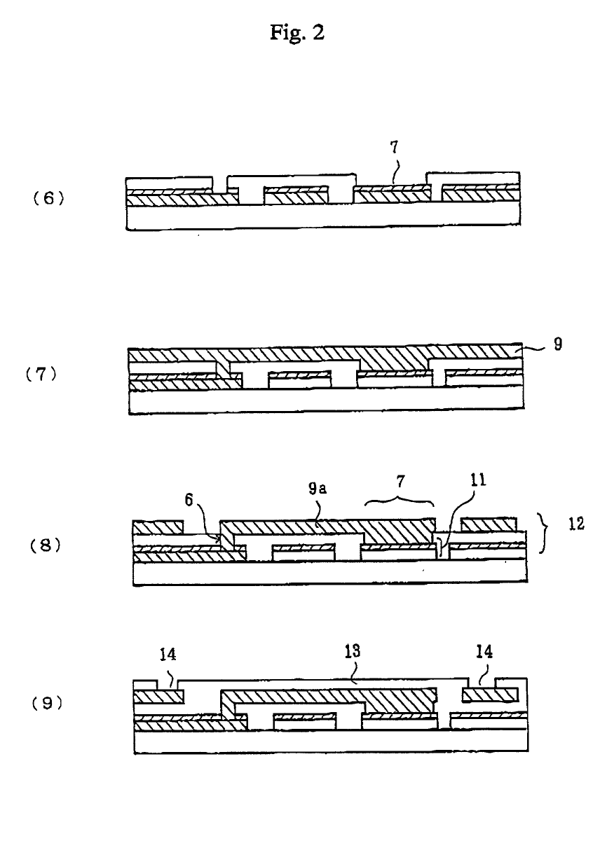

FIGS. 1 and 2 are cross-sectional views of the substantial part of a multilayered wiring board for a wafer batch contact board which show an example of the production process of the multilayered wiring board.

As shown in the step (1) of FIG. 1, a Cr film (not shown) having a thickness of about 400 angstroms, a Cu film 2 having a thickness of about 5.0 μm and a TiO₂ film 3 having a thickness of about 1.11 μm were formed in turn on one surface of a clean glass board 1 having a polished, flat surface (NA40, product of HOYA Co., Ltd., size: 320×320 mm, thickness: 5 mm) by sputtering, thereby forming a Cr/Cu/TiO₂ multilayered wiring layer 4 on the board, with Cr is the closest to the board.

TiO₂ was formed by sputtering using a TiO₂ target and an O₂/Ar mixed gas. TiO₂ may be formed by reactive sputtering using a Ti target and an O₂/Ar mixed gas.

In the multilayered wiring layer 4, Cr is provided for the purpose of enhancing adhesion between the glass and Cu. Cu is a main wiring material. TiO₂ is provided primarily for forming a condenser (dielectric layer). TiO₂ has the functions of preventing oxidation of Cu, enhancing the adhesion to a resist, and preventing a polyimide from remaining at the bottom of a contact hole (via) (when Cu is exposed, a polyimide may remain at the bottom of a via due to the reaction of the polyamide with Cu).

Then, as shown in the step (2) of FIG. 1, a predetermined photolithography procedure (resist coating, exposure, development and etching) was carried out to subject the Cr/Cu/TiO₂ multilayered wiring layer 4 to patterning, thereby forming a first wiring pattern 4a.

To state more specifically, firstly, a resist (MICROPOSIT S1400, product of SHIPLEY) is coated to a thickness of 3 μm, baked at 90° C. for 30 minutes and exposed and developed by using a predetermined mask to form a desired resist pattern (not shown). Using this resist pattern as a mask, firstly, the TiO₂ film 3 is dry-etched by using a fluorine-containing gas (such as a CF₄/O₂ mixed gas) . The TiO₂ film may also be wet-etched by using a fluoride-containing etching solution (such as a mixed solution of hydrofluoric acid and nitric acid) or a chlorine-containing etching solution. Subsequently, the Cu film 2 is etched by using an etching solution such as a ferric chloride aqueous solution, and the Cr film is then etched by using a predetermined etching solution. Thereafter, the resist is removed by using a resist remover, and the resulting multilayered wiring layer 4 is rinsed with water and dried to form the first wiring pattern 4a.

Then, as shown in the step (3) of FIG. 1, a photosensitive polyimide precursor is coated on the first wiring pattern 4a to a thickness of 10 μm by using a spinner or the like to form a polyimide insulating layer 5, and a contact hole 6 and an opening 7 for forming a condenser are formed in the polyimide insulating layer 5.

To state more specifically, the coated photosensitive polyimide precursor is baked at 80° C. for 30 minutes and exposed and developed by using a predetermined mask to form the contact hole 6 and the opening 7 simultaneously. After the photosensitive polyimide precursor is cured in a nitrogen atmosphere at 350° C. for 4 hours to completely convert the precursor into a polyimide, the surface of the polyimide is roughened by oxygen plasma treatment to enhance its adhesion to a second wiring layer to be formed in the next step and to oxidize organic substances such as the residues of the polyimide, developer and the like in the contact hole 6 and the opening 7 to remove the organic substances.

Then, as shown in the step (4) of FIG. 1, a protective resist pattern 8 is formed in the opening 7 for the purpose of protecting the TiO₂ film 3 in the opening 7.

Then, as shown in the step (5) of FIG. 1, the TiO₂ film 3 (insulator) at the bottom of the contact hole 6 is removed since it hinders connection. To state more specifically, the TiO₂ film 3 at the bottom of the contact hole 6 is removed by dry etching using a fluorine-containing gas (such as a CF₄/O₂ mixed gas) or by wet etching using a fluoride-containing etching solution (such as a mixed solution of hydrofluoric acid and nitric acid) or a chlorine-containing etching solution. At that time, the TiO₂ film in the opening 7 is not etched since it is protected by the resist.

Then, as shown in the step (6) of FIG. 2, the protective resist pattern 8 formed in the opening 7 is removed by using a resist remover.

Then, as shown in the step (7) of FIG. 2, a Cr/Cu multilayered wiring layer 9 is formed in the same manner as in the above step (1). In this case, in the present example, since a condenser is not formed between the multilayered wiring layer 9 and the multilayered wiring layer present above the layer 9, a TiO₂ film is not formed on the surface of the multilayered wiring layer 9.

Then, as shown in the step (8) of FIG. 2, the Cr/Cu multilayered wiring layer 9 is subjected to patterning to form a second wiring pattern 9a. A portion of the wiring pattern 9a is used as a condenser counter electrode. Thereby, the upper wiring pattern and the lower wiring pattern are connected (conducted) to each other via the contact hole 6 and, at the same time, a condenser 11 is formed in the opening 7 in a multilayered wiring layer 12.

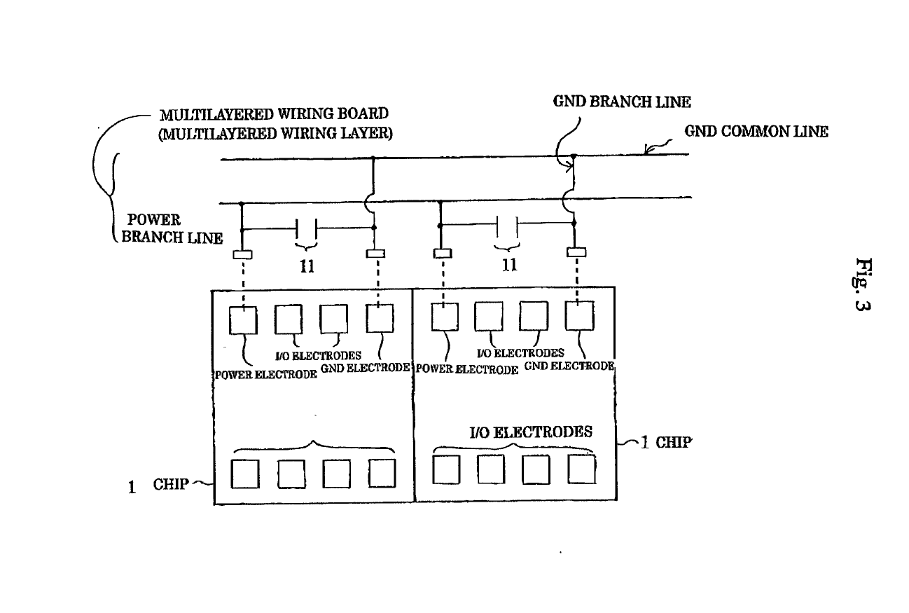

In the present example, as shown in FIG. 3, the condenser 11 was formed for each chip and between a power supply branch line and a ground branch line in the multilayered wiring board.

Further, the area of a condenser electrode (portion overlapping the counter electrode) was 8.3 mm², and the capacity of the condenser was 500 pF.

Then, as shown in the step (9) of FIG. 2, a polyimide was coated on the board as an insulating film, and the insulating film was subjected to patterning to form a protective insulating layer 13 and contact portions (openings) 14. Thus, a multilayered wiring board 10 for a wafer batch contact board was obtained.

Bonding of Anisotropic Conductive Rubber Sheet

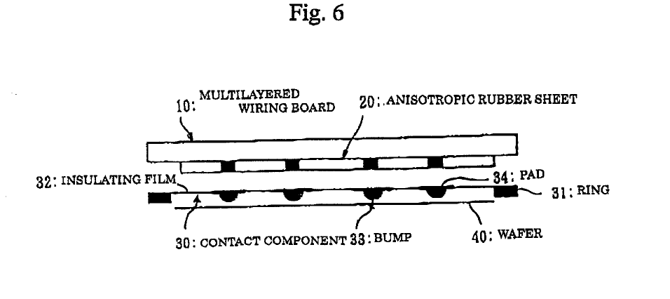

Then, as shown in FIG. 6, an anisotropic conductive rubber sheet 20 which was made of a silicon resin and in which metal particles were embedded at the points corresponding to pad electrodes was bonded to a predetermined position of the multilayered wiring board 10.

Assembly Step

After the above multilayered wiring board 10 with the anisotropic conductive rubber sheet 20 bonded thereto was positioned relative to a contact component 30 without causing the pads to come off, they were bonded to each other. Thus, a wafer batch contact board was completed.

Burn-In Test

After the electrodes on a wafer were positioned relative to the bumps of the contact component, they were fastened by a chuck and put into a burn-in tester to be tested at 125° C. The target to be test was an 8-inch wafer having 400 chips of 64M-DRAMs formed thereon. Further, for comparison, another wafer batch contact board was prepared in the same manner as in the above example except that no condensers were formed.

As a result, when a simultaneous measurement of all chips was carried out by using the board having no condensers formed therein, the operations of the chips were observed only at 10 MHz or lower, while when the simultaneous measurement of all chips was carried out by using the board in which a condenser was formed for each chip, the operations at 20 MHz of all chips could be observed at the same time. Thus, according to the present invention, a board which was more resistant to noises than a conventional board could be prepared.

Further, when the board in which the condenser was formed for each chip was used, the operations at 20 MHz of all chips could be observed at the same time in the cases of, for example, a microprocessor and ASIC as well.

In addition, since the surface of the multilayered wiring board on which multilayered wiring patterns were not formed was flat, the surface exhibited good thermal conductivity to a heater contacting the surface, whereby temperature control could be exercised accurately in the burn-in test.

Furthermore, the TiO₂ dielectric layer in the condenser had neither cracks caused by heat nor degradation of performance caused by heat.

When the capacity of the condenser was out of a range of 50 pF to 0.1 μF, the chips (devices) on the wafer did not operate normally.

### Example 2

A multilayered wiring board for a wafer batch contact board was prepared and a burn-in test was conducted in the same manner as in Example 1 except that after the step (8) in Example 1, a second polyimide insulating film, a contact hole and a third wiring pattern were formed; a third polyimide insulating film, a contact hole and a fourth wiring pattern were then formed in turn; and then the step (9) in Example 1 was carried out to obtain the four-layer wiring glass board.

The results were the same as those of Example 1.

The second wiring pattern and the third wiring pattern each were a multilayered wiring pattern having a Cr/Cu/Ni structure, with Cr being the closest to the board. Ni has the functions of preventing oxidation of Cu, enhancing the adhesion to a resist and preventing a polyimide from remaining at the bottoms of the contact holes.

The fourth wiring pattern which was the uppermost layer was a multilayered wiring pattern having a Cr/Cu/Ni/Au structure, with Cr being the closest to the board, for improving electrical contact with anisotropic conductive rubber.

### Example 3

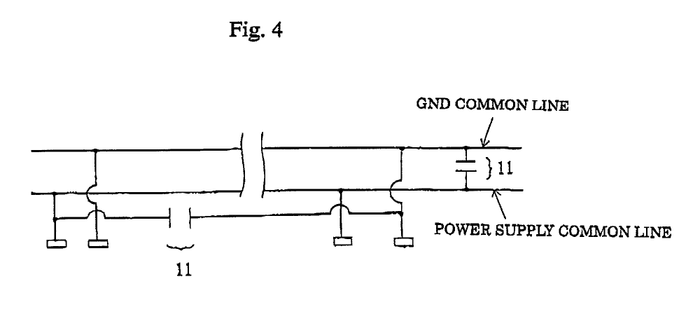

A multilayered wiring board for a wafer batch contact board was prepared and a burn-in test was conducted in the same manner as in Example 1 except that a condenser was provided for a couple of chips as shown in FIG. 4.

As a result, the operations at 20 MHz of all chips could be observed at the same time.

### Example 4

A multilayered wiring board for a wafer batch contact board was prepared and a burn-in test was conducted in the same manner as in Example 1 except that a condenser was provided between a power supply common line and a GND common line as shown in FIG. 4.

As a result, the operations at 12 MHz of all chips could be observed at the same time.

### Example 5

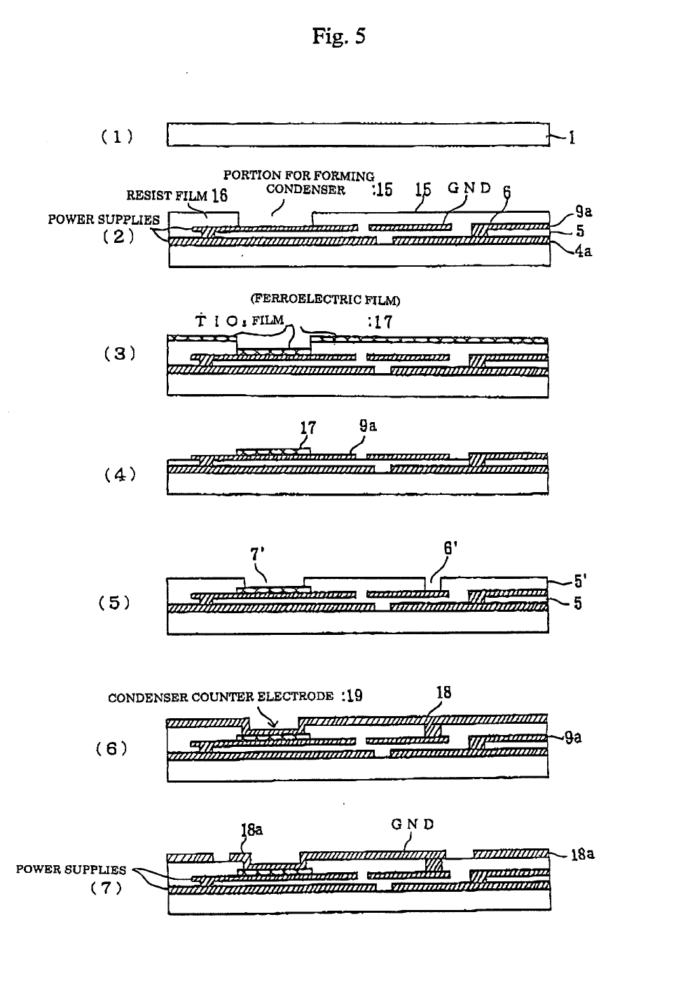

FIG. 5 is a cross-sectional view of the substantial part of a multilayered wiring board for a wafer batch contact board which shows another example of the production process of the multilayered wiring board.

On a glass board 1 shown in the step (1) of FIG. 5, as shown in the step (2), a first wiring pattern 4a was formed, a first polyimide insulating film 5 and a contact hole 6 were formed on the pattern 4a, a second wiring pattern 9a was formed on the film 5 and the hole 6, and a resist layer 16 was formed on the pattern 9a except for a portion 15 for forming a condenser.

Then, as shown in the step (3) of FIG. 5, a TiO₂ film (ferroelectric film) 17 having a thickness of 1.11 μm was formed. TiO₂ was formed by reactive sputtering using a Ti target and an O₂/Ar mixed gas. TiO₂ may also be formed by sputtering using a TiO₂ target and an Ar gas.

Then, as shown in the step (4) of FIG. 5, the resist layer 16 and the TiO₂ film 17 on the resist layer 16 were removed by dissolving and removing the resist layer 16 (lift-off process).

Then, as shown in the step (5) of FIG. 5, a second polyimide insulating film 5′ was formed, and a contact hole 6′ and an opening 7′ for forming a condenser were formed.

Then, as shown in the step (6) of FIG. 5, a third conductive layer 18 was formed. At that time, the conductive layer was also formed not only in the opening 7′ to form a condenser counter electrode 19 but also in the contact hole 6′, whereby the second wiring pattern 9a and the third conductive layer 18 were connected (conducted) to each other.

Then, as shown in the step (7) of FIG. 5, the third conductive layer 18 was subjected to patterning to form a third wiring pattern 18a.

Then, by carrying out the step (9) in Example 1, a three-layer wiring glass board was obtained.

In the present example, as shown in FIG. 3, a condenser 11 was formed for each chip and between a power branch line and a ground branch line in the multilayered wiring board.

Further, the area of a condenser electrode (portion overlapping the counter electrode) was 8.3 mm², and the thickness of the TiO₂ film was 1.11 μm. The capacity of the condenser was 500 pF.

In addition, the first wiring pattern and the second wiring pattern each were a multilayered wiring pattern having a Cr/Cu/Ni structure, with Cr being the closest to the board. Ni has the functions of preventing oxidation of Cu, enhancing the adhesion to the resist and preventing a polyimide from remaining at the bottoms of the contact holes. The third wiring pattern which was the uppermost layer was a multilayered wiring pattern having a Cr/Cu/Ni/Au structure, with Cr being the closest to the board, for improving electrical contact with anisotropic conductive rubber.

When the burn-in test was conducted in the same manner as in Example 1, the operations at 20 MHz of all chips could be observed at the same time.

Further, the TiO₂ layer in the condenser had neither cracks caused by heat nor degradation of performance caused by heat. As for the condenser counter electrode, no degradation of performance caused by oxidation occurred.

### Example 6

A multilayered wiring board for a wafer batch contact board was prepared in the same manner as in Example 5 except that a Ba₂TiO₄ film was formed by a sol-gel method, CVD, vacuum evaporation or sputtering in place of the TiO₂ film in the step (3) of Example 5.

Further, the area of a condenser electrode (portion overlapping a counter electrode) was 19.5 mm², and the thickness of the Ba₂TiO₄ film was 1 μm. The capacity of the condenser was 500 pF.

When the burn-in test was conducted in the same manner as in Example 1, the operations at 20 MHz of all chips could be observed at the same time.

Further, the Ba₂TiO₄ dielectric layer in the condenser had neither cracks caused by heat nor degradation of performance caused by heat and exhibited higher voltage resistance (insulating property) than the TiO₂ dielectric layer of Example 5. As for the condenser counter electrode, no degradation of performance caused by oxidation occurred.

The present invention is not limited to the above Examples and can be modified and practiced as appropriate within the scope of the present invention.

For example, the number of wiring layers in the multilayered wiring board may be 2 to 10 or more. As a multilayered wiring board to be used as a burn-in board, it has 3 to 4 wiring layers for use in a memory, 5 to 6 wiring layers for use in a logic circuit and around 10 layers for use in a hybrid circuit.

Further, although a condenser was formed between the first wiring pattern and the second wiring pattern in the above example, the present invention is not limited to this embodiment, and a condenser may be formed between any wiring patterns one of which is located above the other (for example, between the second wiring pattern and the third wiring pattern or between the first wiring pattern and the third wiring pattern).

The insulating board in the multilayered wiring board for a wafer batch contact board of the present invention is preferably a glass board, a ceramic board, a glass ceramic board or a silicon board.

The glass board in the multilayered wiring board for a wafer batch contact board is not limited to NA40 manufactured by HOYA CORPORATION and may be a board made of a material whose thermal expansion coefficient is the same as or close to that of Si and which is not warped by stress and can be molded with ease. Illustrative examples of boards made of such a material include ceramic boards such as SiC, SiN and alumina, other glass boards (for example, those having almost the same thermal expansion coefficient as that of Si (or having a thermal expansion coefficient of 0.6 to 5 PPM) such as NA35, NA45, SD1 and SD2 (products of HOYA CORPORATION) and PYREX and 7059 (products of CORNING Co., Ltd.)), glass ceramic boards and resin boards (effective particularly when the board is small).

As compared with a ceramic board, a glass board is inexpensive, can be processed with ease, exhibits high flatness when subjected to high-precision polishing, and can be aligned with ease since it is transparent. Further, its thermal expansion can be controlled by the material constituting the glass board. It also has excellent electrical insulating properties. In addition, when the glass board is made of no-alkali glass, no adverse effect caused by the elution of alkali to the surface or the like is produced.

The multilayered wiring board for a wafer batch contact board of the present invention can be used not only in the burn-in test described in the section of “Description of the Related Art” but also in the product inspection (electric characteristic test) which has heretofore been conducted by means of a probe card as well as in wafer level batch CSP inspection. The multilayered wiring board for a wafer batch contact board of the present invention is particularly suitable for use in the test burn-in.

Further, the multilayered wiring board of the present invention is suitable for use in the multilayered wiring board for a probe card or in a high-density multilayered wiring board typified by a multichip module (MCM) board used in high-density mounting. The multilayered wiring board of the present invention can also be used in such applications as a printed board, multilayered TAB and FPC.

In this case, as the insulating board in the multilayered wiring board, a glass board, a ceramic board (such as SiC, SiN or alumina), a glass ceramic board, a silicon board, a glass epoxy board, a polyimide board, a resin board or the like can be used.

According to the multilayered wiring board of the present invention, a condenser can be formed without changing the volume of a board (area, particularly height).

In particular, an ideal structure can be attained in which a condenser is formed for each chip or at least for a couple of chips. Therefore, the errors caused by the noises produced in switching each chip can be eliminated completely or the influence of the noises can be alleviated, so that the characteristics of the board can be fully exploited.

Further, according to the production method of the multilayered wiring board of the present invention, a plurality of condensers can be formed by a simple process at low costs.

The present invention is useful in forming a plurality of condensers on a multilayered wiring board and is particularly useful for a multilayered wiring board for a wafer batch contact board on which an extremely large number of condensers must be formed.

What is claimed is:

1. A multilayered wiring board which constitutes a portion of a contact jig used for testing semiconductor devices and which has the structure that wiring patterns laminated via an insulating layer are connected (or conducted) to each other via a contact hole formed in the insulating layer, wherein condensers having a capacity of 50 pF to 50 μF are formed between the wiring patterns or between lines in the same layer.

2. The board of claim 1, wherein the contact jig is used for inspecting a plurality of semiconductor chips simultaneously, and each of the condensers is provided for one semiconductor chip or for a plurality of semiconductor chips.

3. The board of claim 1, wherein the contact jig is a wafer batch contact board used for testing a plurality of semiconductor chips formed on a wafer at a time, and each of the condensers is provided for one semiconductor chip or for a plurality of semiconductor chips on the wafer.

4. The board of claim 1, wherein the conductive film constituting the condenser is formed in the step in which the wiring pattern is formed.

5. The board of claim 1, wherein the condenser is formed between at least one of power supply lines and a GND line.

6. The board of claim 1, which comprises a power supply common line provided in the multilayered wiring layer for the purpose of electrically connecting the power supply electrodes of the same type in a plurality of semiconductor chips to each other,
a GND common line provided in the multilayered wiring layer for the purpose of electrically connecting the GND electrodes in the plurality of semiconductor chips to each other,
power supply branch lines which branch from the power supply common line and connect the corresponding power supply electrode to the power supply common line,
GND branch lines which branch from the GND common line and connect the corresponding GND electrode to the GND common line, and
a condenser provided between the power supply common line and the GND common line.

7. The board of claim 6, wherein the condenser is formed between a power supply branch line and a ground branch line in the multilayered wiring board which correspond to the power supply electrode and the GND electrode in each of the semiconductor chips, respectively.

8. The board of claim 1, wherein the dielectric material constituting the condenser is a material containing titanium oxide.

9. The board of claim 1, wherein the dielectric layer constituting the condenser has a thickness of 500 angstrom to 20 μm.

10. A method for producing a multilayered wiring board which constitutes a portion of a contact jig used for testing semiconductor devices and has the structure that wiring patterns laminated via an insulating layer are connected (or conducted) to each other via a contact hole formed in the insulating layer, the method including the step of forming a condenser by forming a dielectric layer on a portion of the area where the upper wiring pattern and the lower wiring pattern overlap each other three-dimensionally or the step of forming a condenser by forming a dielectric layer between lines in the same layer on a portion of the area where the lines are close to each other.

11. The method of claim 10, wherein the conductive film constituting the condenser is formed in the step of forming the wiring patterns.

12. The method of claim 11, which further comprises the steps of:
forming a first wiring pattern having a dielectric layer formed on the surface,
forming an insulating layer on the dielectric layer formed on the first wiring pattern,
forming a contact hole for connecting wiring patterns laminated with the insulating layer therebetween to each other in the insulating layer and forming an opening for forming a condenser in the insulating layer,
forming a protective layer in the opening to protect it, removing the dielectric layer exposed in the contact hole, and then removing the protective layer, and
forming a second wiring pattern on the insulating layer, connecting (or conducting) the first wiring pattern and the second wiring pattern to each other via the contact hole and forming a condenser in the opening.

13. The method of claim 11, which further comprises the steps of:
forming a first wiring pattern,
forming an insulating layer on the first wiring pattern,
forming a contact hole for connecting wiring patterns laminated with the insulating layer therebetween to each other in the insulating layer and forming an opening for forming a condenser in the insulating layer,
forming a protective layer at least in the contact hole to protect it, forming a dielectric layer in the opening formed in the insulating layer, and then removing the protective layer, and
forming a second wiring pattern on the insulating layer, connecting (or conducting) the first wiring pattern and the second wiring pattern to each other via the contact hole and forming a condenser in the opening.

14. A contact jig comprising the multilayered wiring board of claim 1 and a contact component which makes direct contact with devices to be inspected.

15. The contact jig of claim 14, which is a wafer batch contact board.

16. A method for inspecting a plurality of semiconductor chips (devices) simultaneously by using the contact jig of claim 14.

17. A method for inspecting a plurality of semiconductor devices formed on a semiconductor wafer by subjecting all the semiconductor devices to a burn-in test simultaneously using the wafer batch contact board of claim 15.

18. A multilayered wiring board having the structure that wiring patterns laminated via an insulating layer are connected (or conducted) to each other via a contact hole formed in the insulating layer, wherein condensers are formed between the wiring patterns or between lines in the same layer in the multilayered wiring layer.
